(19) United States
(12) Patent Application Publication
(10) Pub. No.: US 2011/0192961 A1
(43) Pub. Date: Aug. 11, 2011

(54) SOLID STATE IMAGING DEVICE AND ITS DRIVING METHOD

(75) Inventor: Kazunobu KUWAZAWA, Sakata (JP)

(73) Assignee: SEIKO EPSON CORPORATION, Tokyo (JP)

(21) Appl. No.: 13/011,995

(22) Filed: Jan. 24, 2011

(30) Foreign Application Priority Data
Feb. 10, 2010 (JP) 2010-027159

(51) Int. Cl. H01L 31/112; G01J 1/42

(52) U.S. Cl. 250/214 R; 257/292

(57) ABSTRACT

A solid state imaging device includes a P⁻ well region 3 formed in an N⁻ type layer 2 in a state in which the N⁻ type layer remains in a surface layer of a semiconductor substrate, a photodiode having a light reception region that generates photocharges by light irradiation, a carrier pocket 6 in which the photocharges are accumulated, a P⁺ type high concentration diffusion layer 5 that discharges the photocharges accumulated in the carrier pocket, a modulation gate electrode that is formed over the carrier pocket through a gate dielectric film 1a, and a reset gate electrode 4a that is formed over a portion between the carrier pocket 6 and the P⁺ type high concentration diffusion layer 5 through a gate dielectric film 1b.

The entire disclosure of Japanese Patent Application No. 2010-027159, filed on Feb. 10, 2010, is expressly incorporated by reference herein.

### BACKGROUND

1. Technical Field

The invention relates to solid state imaging devices and their driving methods.

2. Related Art

A solid state imaging device in related art is equipped with a plurality of pixels arranged in a matrix configuration. Each of the pixels includes one photodiode and one transistor. Further, the transistor is provided with an accumulation section where holes would readily gather, which is called a carrier pocket, below the gate electrode. The photodiode generates holes according to the amount of light of incident light. The generated holes are accumulated in the accumulation section. The threshold voltage of the transistor changes according to the number of holes accumulated in the accumulation section. By reading a source voltage that changes according to the change in the threshold voltage, the source voltage according to the amount of light of incident light, in other words, pixel data can be obtained. By using a plurality of pixel data, one set of image data is generated (see, for example, JP-A-2002-134729, paragraphs 0023-0060).

FIG. 8 is a cross-sectional view of a solid state imaging device of related art.

Structure

A photodiode that is a photo detecting section and a modulation transistor are provided adjacent to each other within each unit pixel. The photodiode is arranged next to the modulation transistor. The photodiode and the modulation transistor are formed in a P⁻ well region 13 that is formed inside an N⁻ type layer 12 in a P type silicon substrate 11. At the transistor section, a modulation gate electrode 14 is formed on the surface of the silicon substrate 11 through a gate dielectric film 11a. The N⁻ type layer 12 is also thinly formed on the surface of the silicon substrate 11. A P type layer (a carrier pocket) 16 is formed on the substrate surface below the modulation gate electrode 14 through the N⁻ type layer 12 that serves as a channel. The N⁻ type layer 12 is formed immediately below the carrier pocket 16, thereby separating the P type silicon substrate 11 from the carrier pocket 16.

The modulation gate electrode 14 has a ring shape, and a source region is formed in a manner to be surrounded by an inner periphery of the modulation gate electrode 14, and a drain region is formed in a manner to surround an outer periphery of the modulation gate electrode 14. Further, wirings are electrically connected to the modulation gate electrode 14, the source region and the drain region, respectively.

Operation

Charges generated by light incident on the photodiode are transferred to the carrier pocket 16 below the modulation transistor. As the threshold value of the modulation transistor changes according to the amount of charges transferred, the amount of light incident on the photodiode is detected depending on the amount of the changes. After detection, a high voltage bias is applied to the channel section of the modulation transistor, thereby discharging the charges accumulated in the carrier pocket 16 to the P type silicon substrate 11 below, which completes a series of operations.

The solid state imaging device of related art described above entails the following problems (1)-(5):

(1) Concern of Charge Injection from the Substrate Through the N⁻ Type Layer 12 Below the Carrier Pocket:

According to the solid state imaging device of related art, photoelectrically converted charges are reserved in the carrier pocket 16 below the modulation transistor. Since the carrier pocket 16 needs to be isolated from the P type silicon substrate 11 by the N⁻ type layer 12, a high potential barrier is necessary. If the potential barrier is set low, noise charges may be injected in the carrier pocket 16 from the substrate, which makes it impossible to distinguish between the charge of a signal (S) and the noise charge injected from the substrate. The N⁻ type layer 12 also serves as a path for discharging the charge at the time of charge reset. Therefore, if the potential barrier is set too high, discharging of the charges would become difficult. The charges can be discharged by applying a higher voltage, but this eventually leads to the necessity of providing a drive circuit with a high breakdown voltage, and an increase in the power consumption. Another possible countermeasure may be to reduce the amount of charge that can be accumulated in the carrier pocket 16. But this would deteriorate the fundamental performance of the solid state imaging device, and therefore would not be implemented.

(2) Abnormal Output Through a Current Parasitic Path of the Modulation Transistor at the Time of Readout Operation:

In the solid state imaging device of related art, a readout operation is performed when the modulation transistor is in an H (high) state. In this instance, two paths for an electrical current to flow from the drain to the source are created, i.e., the channel section at the surface, and a path passing through the N⁻ type layer 12 immediately below the carrier pocket 16 (i.e., a parasitic path). In darkness or relatively dim light, the potential on the N⁻ type layer 12 would not become high, so that the current via the parasitic path would not become large. However, when strong light enters the device, the potential on the parasitic path becomes high, such that an output through the parasitic path (i.e., a parasitic output) becomes greater, and an N signal (a noise signal), in particular, would be replaced by a parasitic output on a non-selected wire, which would make the S-N differential output smaller. In the worst case, when there are dim light incident on a selected wire and brighter light incident on a non-selected wire, there is a possibility of no output from the selected wire. As a countermeasure, there is a method to make the parasitic output transparent by lowering the saturation output, and setting the N output value (Vn) at a higher voltage. However, this method has harmful side effects of smaller saturation output and deterioration of the fundamental performance. There is another method to alleviate the parasitic output by forming the N⁻ type layer 12 vertically extending below the source, which defines a portion of the parasitic path, to be shallow. However, if the N⁻ type layer 12 is made shallow, the N type impurity concentration below the source contact becomes lower, such that dark current generated at an interface between metal and Si would be generated much more, which is harmful because it leads to deterioration of the dark time property.

(3) Transfer Potential Barrier Due to Gradual Rising of the N Type Impurity Region (N⁻ Type Layer 12) at the Time of Fabricating the Photodiode (Photoelectric Convertor Device):

The photodiode is fabricated by high-energy ion implantation. The ion implantation is applied only to an aperture portion for the photodiode, using a resist mask. In this instance, at a resist boundary (an end section of the resist mask), ions are implanted through a tapered end of the resist layer. Therefore, when viewed in plan view, N type impurity at the boundary of the photodiode has a structure with a profile gradually rising from a deeper region to a shallower region of the silicon substrate 11. By positively using this feature, the photodiode is fabricated. However, this gradually rising profile would also function to cut the path of charges to be transferred from the photodiode to the carrier pocket 16 of the modulation region. For this reason, restrictions are imposed on the condition for ion implantation. In particular, when it is desired to perform ion implantation with higher energy, the tendency in cutting the path becomes greater, which sets the limit to forming a photodiode deeper. As a result, the weak red sensitivity would lower, leading to a harmful effect of deteriorating the fundamental property.

(4) Formation of a Transfer Potential Dip Due to Gradual Rising of the P Type Impurity Region at the Time of Forming the P Type Reset Enhancing Region in the P Type Silicon Substrate 11 Below the Modulation Transistor:

This phenomenon occurs in a manner similar to (3) above. The P type reset enhancing region with higher impurity concentration formed by implanting P type impurity is formed in the P type silicon substrate 11 located below the N⁻ type layer 12 below the carrier pocket 16. If the reset enhancing region is not formed, failures in which reset charges cannot be effectively discharged may occur. The P type reset enhancing region is formed by high energy ion implantation. The ion implanted P type impurity gradually rises at the boarder (the boarder of the aperture region) of the photodiode, so that the P type impurity in the transfer path from the photodiode to the carrier pocket 16 would have a high concentration. For this reason, a potential dip is formed, which not only causes transfer failures, but also may allow carriers accumulated in the dip to leak out at undesired moments to become noise components. Also, in the worst case, the potential on the N⁻ type layer 12 between the transfer path and the reset enhancing region is lowered, which may lead to a harmful effect in which photoelectrically converted charges pass through the substrate without being property transferred. In order to avoid such a harmful effect, restrictions are imposed on the condition for ion implantation for forming the reset enhancing region, and careful attention needs to be paid to ion implantation direction and ion implantation energy.

(5) Generation of Knee Characteristic:

When light in an amount exceeding the saturation charge amount of the carrier pocket 16 that is a charge accumulation section is incident on the solid state imaging device of related art, generated charges move from the photodiode to the carrier pocket 16, and discharged from the carrier pocket 16 into the charge discharging path in the substrate. However, when particularly strong light enters the device, more charges flow into the carrier pocket 16 than charges discharged into the charge discharge path in the substrate, such that more charges than the saturation charge amount that can essentially be accumulated would be accumulated in the carrier pocket 16. This causes a problem in that a Knee characteristic appears.

The failures described above are originated from the presence of the N⁻ type layer 12, and the necessity of discretely forming the diffusion layers for the photodiode and the modulation transistor in a plane, which are hindrance to improvement in the device characteristics and lower voltage implementation.

### SUMMARY

In accordance with an advantage of some aspects of the invention, a solid state imaging device which solves at least one of the problems described above and its driving method are provided.

An embodiment of the invention pertains to a solid state imaging device equipped with a photodiode, a light signal detection transistor and a reset transistor. The solid state imaging device includes a first conductivity type diffusion layer formed in a semiconductor substrate; a photodiode equipped with a light reception region that has a second conductivity type diffusion layer formed in the first conductivity type diffusion layer in a state in which the first conductivity type diffusion layer remains in a surface layer of the semiconductor substrate, and generates photocharges by light irradiation; a carrier pocket that is formed in the second conductivity type diffusion layer and accumulates the photocharges; a second conductivity type charge discharging diffusion layer that is formed in the first conductivity type diffusion layer and arranged next to the carrier pocket for discharging the photocharges accumulated in the carrier pocket; a gate dielectric film that is formed on the semiconductor substrate, formed over the carrier pocket, and formed over a portion between the carrier pocket and the charge discharging diffusion layer; a light signal detection gate electrode that is formed over the carrier pocket through the gate dielectric film; a reset gate electrode that is formed over a portion between the carrier pocket and the charge discharging diffusion layer through the gate dielectric film; and a source section and a drain section that are formed at the first conductivity type diffusion layer. In one aspect, the light signal detection transistor includes the light signal detection gate electrode, the gate dielectric film, the source section and the drain section, and controls output of a threshold voltage that is modulated by the photocharges accumulated in the carrier pocket as a light signal; and the reset transistor includes the reset gate electrode and the gate dielectric film, and controls discharge of the photocharges accumulated in the carrier pocket to the charge discharging diffusion layer.

According to the solid state imaging device described above, as the first conductivity type diffusion layer (for example, N-type layer) below the carrier pocket like the related art is eliminated, at least one of the problems of the related art can be solved.

In the solid state imaging device according to an aspect of the embodiment of the invention, the gate dielectric film of the reset transistor may preferably have a film thickness smaller than that of the gate dielectric film of the light signal detection transistor.

Further, in the solid state imaging device in accordance with another aspect of the embodiment of the invention, the photodiode may preferably be formed below the carrier pocket.

In the solid state imaging device in accordance with still another aspect of the embodiment of the invention, each of the carrier pocket and the gate electrode has a plane configuration that may preferably be a ring shape.

In the solid state imaging device in accordance with yet another aspect of the embodiment of the invention, the first conductivity type may be N type, and the second conductivity type may be P type.

Another embodiment of the invention pertains to a method for driving one of the solid state imaging devices described above, and the method includes: conducting an accumulation operation in which photocharges are generated by the photodiode through light irradiation to the light reception region, and the photocharges are accumulated in the carrier pocket; conducting a signal modulation operation in which a first gate voltage is applied to the light signal detection gate electrode in a state in which the threshold voltage of the light signal detection transistor is changed by the photocharges accumulated in the carrier pocket, a drain voltage is applied to the drain section, and a second gate voltage is applied to the reset gate electrode, thereby detecting a signal from the source section; conducting a reset operation in which a voltage higher than the first gate voltage is applied to the light signal detection gate electrode, the drain voltage is applied to the drain section, and a voltage lower than the second gate voltage is applied to the reset gate electrode, thereby forming a charge discharging path between the carrier pocket and the charge discharging diffusion layer to discharge the photocharges remaining in the carrier pocket; and conducting a noise modulation operation in which the first gate voltage is applied to the light signal detection gate electrode in a state in which photocharges are not accumulated in the carrier pocket, the drain voltage is applied to the drain section, and the second gate voltage is applied to the reset gate electrode, thereby detecting a signal from the source section as a noise signal.

### BRIEF DESCRIPTION OF THE DRAWINGS

FIG. 1 is a plan view of a solid state imaging device in accordance with a first embodiment of the invention.

FIG. 2 is a cross-sectional view of the structure of a portion taken along a line A-A′ of FIG. 1.

FIG. 3 is a potential diagram in a portion along a line X-X′ in the structural cross-sectional view of FIG. 2 at the time of modulation.

FIG. 4 is a potential diagram in the portion along the line X-X′ in the structural cross-sectional view of FIG. 2 at the time of reset.

FIG. 5 is a diagram of an equivalent circuit of the solid state imaging device shown in FIG. 1 and FIG. 2.

FIG. 6 shows charts showing a driving sequence of the solid state imaging device shown in FIG. 1 and FIG. 2.

FIG. 7 is a plan view of a solid state imaging device in accordance with a second embodiment of the invention.

FIG. 8 is a cross-sectional view of a solid state imaging device of related art.

### DESCRIPTION OF EXEMPLARY EMBODIMENTS

Preferred embodiments of the invention are described in detail below with reference to the accompanying drawings. The person having ordinary skill in the art should readily understand, however, that the invention is not limited to the following description, and many changes can be made to the embodiments and their details without departing from the subject matter of the invention and its scope. Accordingly, the invention should be construed without being limited to the details of the description of the embodiments shown below.

### First Embodiment

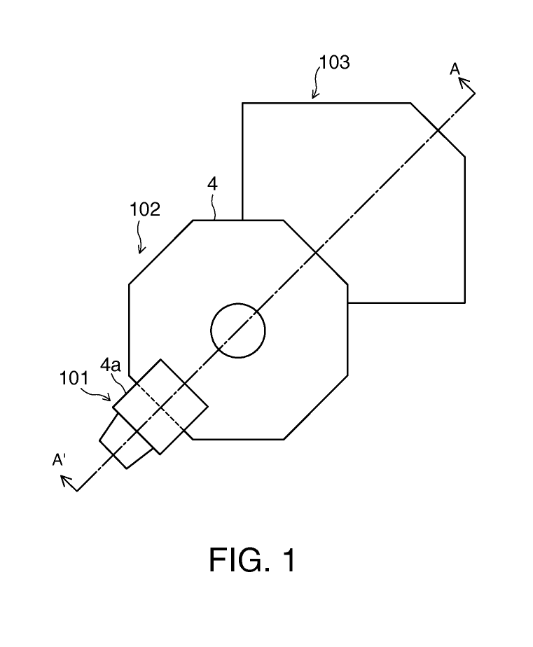

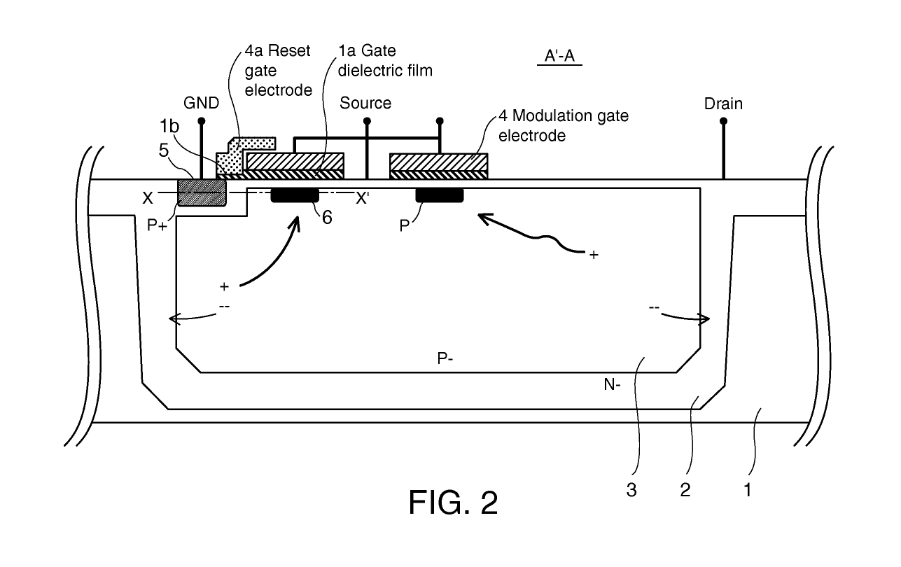

FIG. 1 is a plan view of a substrate modulation type solid state imaging device in accordance with an embodiment of the invention. FIG. 2 is a cross-sectional view taken along a line A-A′ of FIG. 1.

Structure

As shown in FIG. 1, within a unit pixel of the solid state imaging device, a photodiode 103 and a modulation transistor (a light signal detection transistor) 102 are provided. The unit pixels are arranged at equal pitches in vertical and horizontal directions, and oriented diagonally with respect to columns or rows.

As shown in FIG. 2, the solid state imaging device has, for example, a P type silicon substrate 1 as a semiconductor substrate, and an N⁻ type layer 2, for example, as a first conductivity type diffusion layer is formed in the P type silicon substrate 1. A P⁻ well region 3, for example, as a second conductivity type diffusion layer is formed within the N⁻ type layer 2, and a photodiode 103 is formed in the P⁻ well region 3. The photodiode 103 is equipped with a light reception region that generates photocharges by light irradiation. Also, the N⁻ type layer 2 is left remained on the P⁻ well region 3 (i.e., on the surface layer of the silicon substrate 1).

A carrier pocket (P type layer) 6 in which photocharges are accumulated is formed within the P⁻ well region 3, and the carrier pocket 6 has a plane configuration in a ring shape. Also, a photodiode that is a charge generation region is also formed immediately below the carrier pocket 6.

A P⁺ type high concentration diffusion layer 5 is formed in the N⁻ type layer 2 as a second conductivity type charge discharging diffusion layer for discharging photocharges accumulated in the carrier pocket 6. The P⁺ type high concentration diffusion layer 5 is arranged next to the carrier pocket 6, located at the substrate surface, and located outside of the P⁻ well region 3.

Gate dielectric films 1a and 1b are formed on the surface of the P type silicon substrate 1. The gate dielectric films 1a and 1b are located above the carrier pocket 6, and are located over a portion between the carrier pocket 6 and the P⁺ type high concentration diffusion layer 5. As to the film thickness of the gate dielectric films 1a and 1b, the portion 1b formed over a portion between the carrier pocket 6 and the P⁺ type high concentration diffusion layer 5 is formed thinner than the portion 1a that is formed over the carrier pocket 6.

A modulation gate electrode (a light signal detection gate electrode) 4 is formed on the gate dielectric film 1a. The modulation gate electrode 4 has a plane configuration in a ring shape. Also, a reset gate electrode 4a is formed on the gate dielectric film 1b. The reset gate electrode 4a is formed to have an overhang extending over a portion of the modulation gate electrode 4, as shown in FIG. 2. The reset gate electrode 4a and the modulation gate electrode 4 are insulated from each other by an unshown isolation insulating film. The isolation insulating film has a film thickness of 10-50 nm, and may be a silicon oxide film formed by thermally oxidizing the surface of the modulation gate electrode 4 that is composed of polysilicon, or a silicon oxide film formed by a CVD (chemical vapor deposition) method.

According to the present embodiment, the reset gate electrode 4a is formed to overhang over a portion of the modulation gate electrode 4. However, the reset gate electrode 4a may be formed in the same layer as the modulation gate electrode 4 without having an overhang configuration.

By making the reset gate electrode 4a to function, a charge discharging path through which charges are discharged from the carrier pocket 6 to the P⁺ type high concentration diffusion layer 5 is formed in the channel region below the gate dielectric film 1b. The charge discharging path is formed in the same plane as the modulation transistor in a lateral direction.

The reset transistor 101 includes the reset gate electrode 4a and the gate dielectric film 1b, and controls photocharges accumulated in the carrier pocket 6 so as to be discharged to the P⁺ type high concentration diffusion layer 5.

A source section is formed in the N⁻ type layer 2 surrounded by an inner periphery of the modulation gate electrode 4, and a drain section is formed in the N⁻ type layer 2 surrounding an outer periphery of the modulation gate electrode 4. Also, wirings are electrically connected to the modulation gate electrode 4, the source section and the drain section, respectively.

The modulation transistor 102 includes the modulation gate electrode 4, the gate dielectric film 1a, the N⁻ type layer 2 that servers as a channel, a source section and a drain section, and controls the threshold voltage modulated by the photocharges accumulated in the carrier pocket 6 to be outputted as an optical signal.

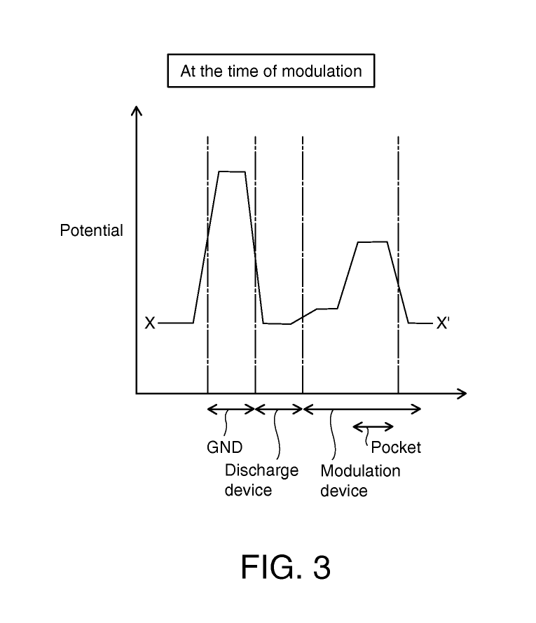

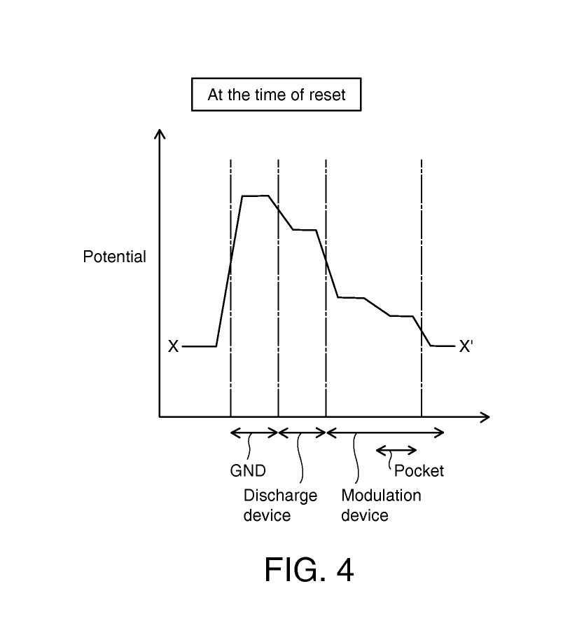

FIG. 3 is a potential diagram of a portion of the device along a line X-X′ of the structural cross-sectional view of FIG. 2 at the time of modulation. FIG. 4 is a potential diagram of a portion of the device along the line X-X′ of the structural cross-sectional view of FIG. 2 at the time of reset.

Operation

Charges (for example, holes) are generated in the substrate by light incident on the photodiode, and the charges are transferred to the carrier pocket 6 below the modulation transistor. As shown in FIG. 3, the modulation transistor has a substrate bias applied thereto when charges are accumulated in the carrier pocket 6, and therefore its threshold value changes according to the amount of charges. The amount of the change is detected as the amount of light entered the photodiode. After detection, the reset transistor is used to make the reset gate electrode function, thereby discharging the charges from the carrier pocket 6 to the P+ type high concentration diffusion layer 5, whereby a series of operations is completed.

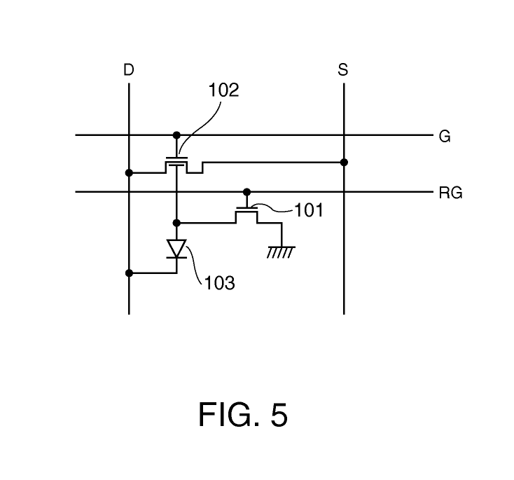

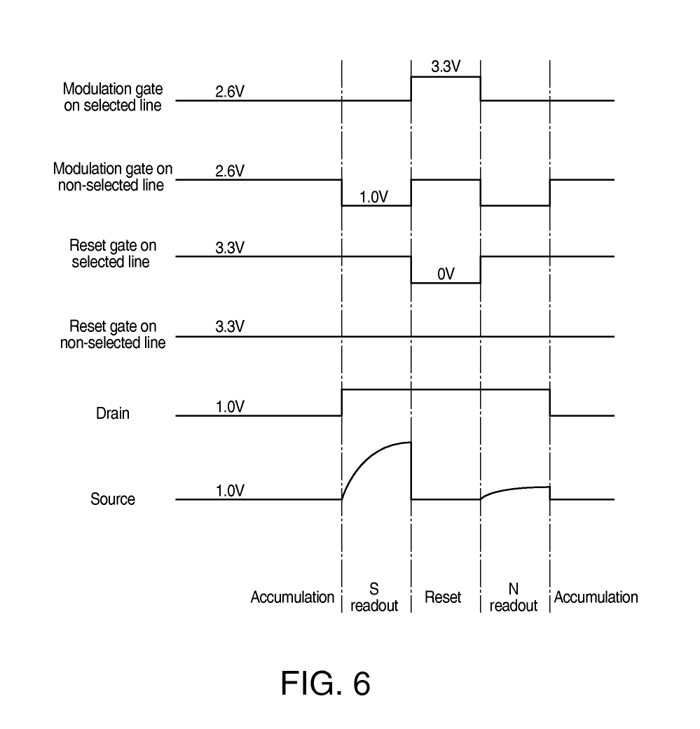

FIG. 5 is a diagram of an equivalent circuit of the solid state imaging device shown in FIG. 1 and FIG. 2. FIG. 6 shows charts showing a driving sequence of the solid state imaging device shown in FIG. 1 and FIG. 2. FIG. 5 shows an equivalent circuit of a single solid state imaging device, and a solid state imaging apparatus is formed from a plurality of such solid state imaging devices arranged in a matrix configuration (for example, arranged in a matrix of 500 rows and 500 columns).

As shown in FIG. 5, the N⁻ type layer 2 of the photodiode 103 is electrically connected to a common drain line D, and the common drain line D is electrically connected to the drain section of the modulation transistor 102. The source section of the modulation transistor 102 is electrically connected to a source line S. The gate electrode 4 of the modulation transistor 102 is electrically connected to a gate line G. The P⁻ well region 3 of the photodiode 103 is electrically connected to the carrier pocket 6. The carrier pocket 6 is electrically connected to the source section or the drain section of the reset transistor 101, and the drain section or the source section of the reset transistor 101 is connected to a ground potential. Also, the reset gate electrode of the reset transistor 101 is electrically connected to a reset gate line RG.

Next, referring to FIG. 5 and FIG. 6, a method for driving the solid state imaging device will be described. It is noted, however, that application voltages to be described specifically hereunder are merely examples, and the invention should be construed without being limited to the specific application voltages.

First, a photocharge accumulation operation is described. A first gate voltage (for example, 2.6 V) is applied to the modulation gate electrodes of the modulation transistors 102 of selected and non-selected pixels through selected gate lines G and non-selected gate lines, a second gate voltage (for example, 3.3 V) is applied to the reset gate electrodes of the reset transistors 101 of the selected and non-selected pixels through selected reset gate lines RG and non-selected reset gate lines, and a drain voltage (for example, 1.0 V) is applied to the drain sections of the modulation transistors 102 through the common drain lines D. Then, photocharges are generated by light entered the photodiodes 103 through their aperture regions. Holes among the photocharges generated in the photodiodes 103 are collected, and the holes are accumulated in the carrier pockets.

Next, a signal modulation operation (S readout) for detecting the amount of photocharges is described. The threshold voltage of the modulation transistors 102 changes by the photocharges accumulated in the carrier pockets. In this state, a first gate voltage (for example, 2.6 V) is applied to the modulation gate electrodes of the selected pixels through the selected gate lines G, a second gate voltage (for example, 3.3 V) is applied to the reset gate electrodes of the selected pixels through the selected reset gate lines RG, and a drain voltage (for example, a voltage higher than 1.0 V) is applied to the drain sections of the modulation transistors 102 through the common drain lines D. For the non-selected pixels, a voltage lower than the first gate voltage (for example, 1.0 V) is applied to the modulation gate electrodes thereof through the non-selected gate lines, and a second gate voltage (for example, 3.3 V) is applied to the reset gate electrodes of the non-selected pixels through the non-selected reset gate lines. Then, the potential on the non-selected source sections that change together with the gate voltage is made lower than the potential on the source sections of the selected pixels to thereby select pixels, and signals from the selected pixels are detected.

Next, a reset operation is described. By the reset operation, carriers remaining in the carrier pockets and the P⁻ well regions 3 are discharged. More specifically, a voltage higher than the first gate voltage (for example, 3.3 V) is applied to the modulation gate electrodes of the modulation transistors 102 of the selected pixels, the first gate voltage (for example, 2.6 V) is applied to the modulation gate electrodes of the non-selected pixels, a voltage lower than the second gate voltage (for example, 0 V) is applied to the reset gate electrodes of the reset transistors 101 of the selected pixels, the second gate voltage (for example 3.3 V) is applied to the reset gate electrodes of the non-selected pixels, and a drain voltage (for example, a voltage higher than 1.0 V) is applied to the drain sections of the modulation transistors 102 through the common drain lines D. Accordingly, a rapid potential change occurs on the P⁻ well region 3 (see FIG. 3 and FIG. 4), such that an electric field strong enough to discharge the photocharges to the P⁺ type high concentration diffusion layer 5 is applied, by which a charge discharging path is formed between the carrier pocket and the P⁺ type high concentration diffusion layer 5, through which the remaining photocharges are securely discharged. In this instance, the potential on the source sections of the modulation transistors 102 is in a floating state.

Next, a noise modulation operation (N readout) is described. By the noise modulation, a signal modulation operation (S readout) is performed in a state in which, after reset, photocharges are not yet accumulated. The bias condition, etc. are similar to those used on the signal modulation operation.

By the noise modulation operation, a difference in threshold value of each of the pixels can be obtained as a noise signal Vn. By subtracting the obtained noise modulation signal Vn from the signal modulation signal Vs obtained in the sequence described above, the net photocharge signal can be extracted as an image signal. By the device for detecting image signals, distribution and variation in threshold values among the pixels can be cancelled out, such that pixel signals having a higher SN ratio can be extracted.

After completing the noise modulation operation, the accumulation operation is performed again; and by repeating this operation cycle, an image signal is outputted.

According to the embodiment described above, the gate potential on non-selected lines can be set low, for example, at 1.0 V, at the time of readout. In the above embodiment, it is set at 1.0 V as an example, but a voltage setting at 0 V is also possible. By setting the voltage at 0 V, an intermediate potential can be eliminated, whereby the circuit scale can be reduced.

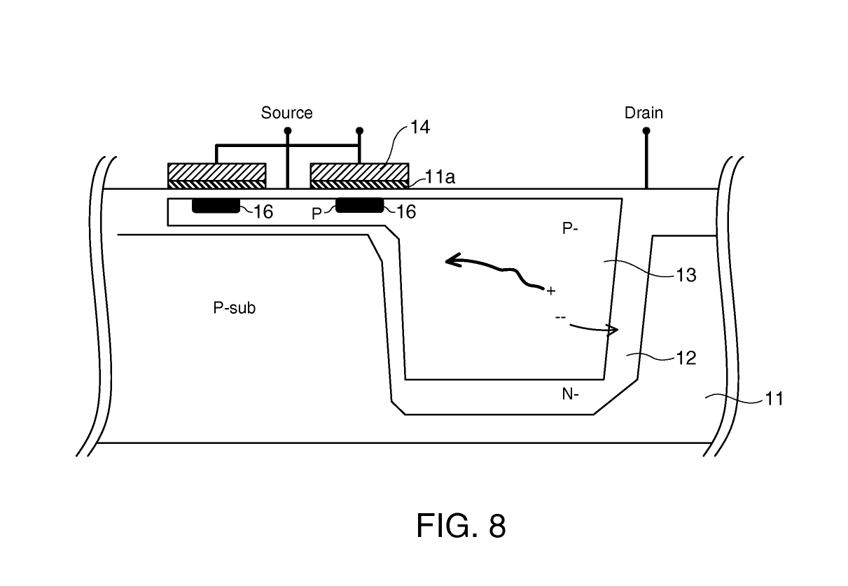

Also, according to the embodiment described above, the N⁻ type layer below the carrier pocket 16 shown in FIG. 8 can be eliminated, the photodiode can also be formed below the modulation transistor, the photodiode can be placed in the entire area except the isolation region in a portion between the P+ type high concentration diffusion layer 5 and the solid state imaging device, and the charge discharging path in a lateral direction which can discharge charges at a low voltage can be formed. Accordingly, the problems in the related art can be solved as follows.

(1) Concern of Charge Injection from the Substrate:

As the N⁻ type layer below the carrier pocket, which becomes to be a barrier against accumulating charges, and defines a reset path at the time of reset, is eliminated, a concern of reverse injection of charges from the substrate can be removed, and the potential on the carrier pocket can be set deeper than the current status. As a result, the amount of charges to be handled can be increased, such that an imaging device having a wide dynamic range and a noise tolerant characteristic can be realized.

(2) Abnormal Output at the Time of Reading Through a Current Parasitic Path of the Modulation Transistor:

Because parasitic paths are eliminated, abnormal outputs at the time of readout do not occur. Also, the structural design of the N type impurity diffusion layer that longitudinally extends below the source can be done without any concern of parasitic paths, such that an imaging device with few dark current and better characteristic can be realized.

(3) Transfer Potential Barrier Due to Gradual Rising of the N Type Impurity Region at the Time of Forming the Photodiode (the Photoelectrical Converter Device):

In the manufacturing process, the step in which a transfer potential barrier is created is eliminated, such that transfer failures would not occur, and the degree of freedom in impurity injection for forming photodiodes is enhanced, such that photodiodes suitable for required characteristics can be manufactured. For example, in order to increase the red sensitivity, it is desirable to form a photodiode deeper. As the energy for forming a photodiode can be set at a high level, its characteristic can be readily improved.

(4) Formation of a Transfer Potential Dip Due to Gradual Rising of the P Type Impurity Region at the Time of Forming the P Type Reset Enhancing Region in the P Type Silicon Substrate Below the Modulation Transistor:

Reset enhancing regions become unnecessary, such that gradual rising of P type impurity would not occur, the transfer potential dip is eliminated, and transfer failures and noise components can be reduced, such that the characteristics can be improved.

It is noted that the present embodiment is described as to a front surface irradiation type solid state imaging device in which light is irradiated from the front surface side of the P type silicon substrate. However, the invention is also applicable to a back surface irradiation type solid state imaging device in which light is irradiated from the back surface side of the silicon substrate.

### Second Embodiment

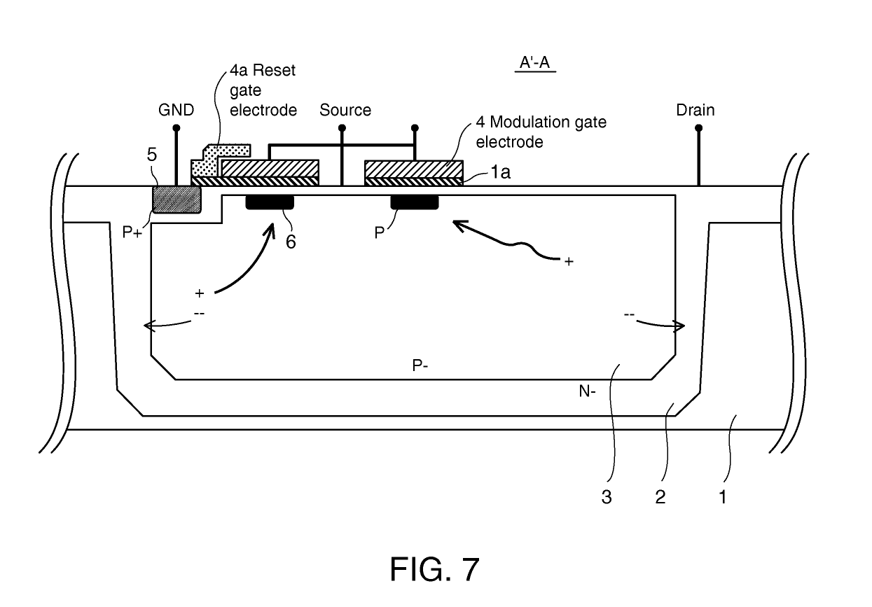

FIG. 7 is a plan view of a solid state imaging device in accordance with a second embodiment of the invention. Portions identical with those shown in FIG. 2 will be appended with the same reference numbers, and only differences will be described.

As shown in FIG. 7, the film thickness of the gate dielectric film 1a below the reset gate electrode 4a is the same as the film thickness of the gate dielectric film 1a below the modulation gate electrode 4.

According to the second embodiment, effects similar to those of the first embodiment can be obtained.

What is claimed is:

1. A solid state imaging device having a photodiode, a light signal detection transistor and a reset transistor, the solid state imaging device comprising:
a first conductivity type diffusion layer formed in a semiconductor substrate;
a photodiode equipped with a light reception region that has a second conductivity type diffusion layer formed in the first conductivity type diffusion layer in a state in which the first conductivity type diffusion layer remains in a surface layer of the semiconductor substrate, and generates photocharges by light irradiation;
a carrier pocket that is formed in the second conductivity type diffusion layer and accumulates the photocharges;
a second conductivity type charge discharging diffusion layer that is formed in the first conductivity type diffusion layer and arranged next to the carrier pocket for discharging the photocharges accumulated in the carrier pocket;
a gate dielectric film that is formed on the semiconductor substrate, formed over the carrier pocket, and formed over a portion between the carrier pocket and the charge discharging diffusion layer;
a light signal detection gate electrode that is formed over the carrier pocket through the gate dielectric film;
a reset gate electrode that is formed over a portion between the carrier pocket and the charge discharging diffusion layer through the gate dielectric film; and
a source section and a drain section that are formed at the first conductivity type diffusion layer,
the light signal detection transistor including the light signal detection gate electrode, the gate dielectric film, the source section and the drain section, and controlling output of a threshold voltage that is modulated by the photocharges accumulated in the carrier pocket as a light signal; and
the reset transistor including the reset gate electrode and the gate dielectric film, and controlling discharge of the photocharges accumulated in the carrier pocket to the charge discharging diffusion layer.

2. A solid state imaging device according to claim 1, wherein the gate dielectric film of the reset transistor has a film thickness smaller than a film thickness of the gate dielectric film of the light signal detection transistor.

3. A solid state imaging device according to claim 1, wherein the photodiode is formed below the carrier pocket.

4. A solid state imaging device according to claim 1, wherein each of the carrier pocket and the gate electrode has a plane configuration that is a ring shape.

5. A solid state imaging device according to claim 1, wherein the first conductivity type is N type, and the second conductivity type is P type.

6. A method for driving the solid state imaging device recited in claim 1, the method comprising:
conducting an accumulation operation in which photocharges are generated by the photodiode through light irradiation to the light reception region, and the photocharges are accumulated in the carrier pocket;
conducting a signal modulation operation in which a first gate voltage is applied to the light signal detection gate electrode in a state in which the threshold voltage of the light signal detection transistor is changed by the photocharges accumulated in the carrier pocket, a drain voltage is applied to the drain section, and a second gate voltage is applied to the reset gate electrode, thereby detecting a signal from the source section;
conducting a reset operation in which a voltage higher than the first gate voltage is applied to the light signal detection gate electrode, the drain voltage is applied to the drain section, and a voltage lower than the second gate voltage is applied to the reset gate electrode, thereby forming a charge discharging path between the carrier pocket and the charge discharging diffusion layer to discharge the photocharges remaining in the carrier pocket; and
conducting a noise modulation operation in which the first gate voltage is applied to the light signal detection gate electrode in a state in which photocharges are not accumulated in the carrier pocket, the drain voltage is applied to the drain section, and the second gate voltage is applied to the reset gate electrode, thereby detecting a signal from the source section as a noise signal.
